(19) United States
(12) Patent Application Publication
(10) Pub. No.: US 2026/0059645 A1
(43) Pub. Date: Feb. 26, 2026

(54) VERTICAL INTEGRATED VOLTAGE REGULATOR WITH CIRCUIT BOARD CUTOUT

(71) Applicant: Arm Limited, Cambridge (GB)

(72) Inventors: Yimajian Yan, Santa Clara, CA (US); Javier DeLaCruz, San Jose, CA (US); Stuart James Aitken, Cambridge (GB); Rainer Herberholz, Great Abington (GB); Sumant Srikant, Cambridge (GB); George John Scott, Chandler, AZ (US); Peter Andrew Rees Williams, Great Abington (GB); Jianlin Zheng, Santa Clara, CA (US)

(21) Appl. No.: 19/292,796

(22) Filed: Aug. 6, 2025

Related U.S. Application Data
(60) Provisional application No. 63/685,562, filed on Aug. 21, 2024.

(51) Int. Cl. H05K 1/02; H05K 3/30; H05K 3/34

(52) U.S. Cl. CPC H05K 1/0203; H05K 3/303; H05K 3/3426; H05K 2201/09063; H05K 2201/09072; H05K 2201/10325; H05K 2201/10378; H05K 2201/10416; H05K 2201/10515; H05K 2201/1053; H05K 2201/10537; H05K 2201/10628

(57) ABSTRACT

An integrated circuit assembly comprises an integrated circuit die and a substrate coupled to the integrated circuit die on a first mounting surface of the substrate. A printed circuit board has a hole formed therein, and is connected to the substrate connected on a second mounting surface of the substrate. A vertically integrated voltage regulator assembly comprises one or more inductors and one or more voltage regulation circuits, and is connected to the substrate at a physical location on a second mounting surface of the substrate opposite the first mounting surface of the substrate. At least a portion of the vertically integrated voltage regulator assembly and at least a portion of the substrate are intersected by an axis normal to and through the first and second mounting surfaces of the substrate, and the vertically integrated voltage regulator is disposed at least partially within the hole in the printed circuit board.

This application claims the benefit of priority under 35 USC § 119(e) to U.S. Provisional Ser. No. 63/685,541 filed on Aug. 21, 2024 and titled VERTICAL INTEGRATED VOLTAGE REGULATOR, which is hereby incorporated herein by reference in its entirety.

### FIELD

The field relates to powering integrated circuit devices, and more specifically to a vertical integrated voltage regulator for integrated circuits with a circuit board cutout.

### BACKGROUND

Modern computerized devices process and store information in a variety of ways, including using processors that may have multiple cores and cache memory that may be associated with each of at least some of the processor cores. The processors in modern high-performance consumer electronics devices such as smart phones, tablet computers, set top boxes, and the like, may have different processor cores with different capabilities, such as high-performance processor cores that can perform a high number of operations per second but that may consume a significant amount of power, and efficient cores that may perform tasks more efficiently but at a lower peak number of instructions per second than high performance cores. In some further examples, at least some of the high-performance cores and/or efficient cores may have configurable performance levels, such as underdriven or overdriven voltage levels and corresponding faster or reduced operating speeds.

Processor cores in some examples may be powered up or down as needed, and in further examples may have one or more different available performance levels (and associated efficiency levels) per core. For example, a demanding video game involving rendering many objects in real time may use both high-performance cores and all the high-efficiency cores in a smartphone, while a simple task like reading email may use a single high-efficiency core. Cores may therefore be selectively powered up or selectively employed to process program instructions depending on the task load in a computing device, typically involving significant changes in power demand as different processor cores are made active or employed to process instructions.

A large integrated circuit die may also have variances in semiconductor behavior across the die or between dies (sometimes known as process corner variances), and voltages needed for different clock frequencies or performance levels of different cores may also vary significantly. Individual control of voltages for each processor core or group of processor cores is therefore desirable in some multi-core computing systems to minimize power consumption by providing each core with no more than the voltage required for reliable operation at a given performance level or clock frequency. High granularity of voltage level provided to different processor cores in a computing system via voltage regulation external to the integrated circuit die may simplify power delivery to the die, but may present challenges related to the physical wire distance and impedance between the voltage regulator and the integrated circuit die.

Multi-core processors in modern computing systems may also have their own cache memory, such as a dedicated level one (L1) or level two (L2) cache memory associated with some or all of the respective processor cores in the multi-core processor. L1 or L2 cache local to one or more processor cores may store frequently-used data local to the respective cores, which may make retrieval of this often-used data faster than if the same data was retrieved from Level 3 (L3) cache or main memory (or DRAM) that is typically slower and physically more remote. Cache memory may typically contain tens of thousands or hundreds of thousands (or more) of words of data per core, comprising a significant percentage of the die area, transistor count, and power consumed by the integrated device, and may be powered up and down or switched between active and inactive power states as processor cores are powered up and down.

When processor cores are powered on to provide greater computing resources for a computing system, they may quickly draw significantly more current than before the cores and cache were powered, potentially causing a droop in voltage provided to the processor circuits. High-performance application such as servers configured to process artificial intelligence workloads may further contain thousands of cores, including hundreds of cores per integrated circuit, drawing power exceeding a kilowatt. Providing power to such cores through a voltage regulator on a motherboard may present some difficulty due to the physical distance and impedance between the voltage regulator circuitry and the integrated circuit die. Voltage regulators are often therefore designed to provide high current capability to an integrated circuit die while limiting effects such as voltage droop. But, voltage regulator circuitry may be slow to respond due to factors such as physical distance and impedance between the voltage regulator and integrated circuit. For reasons such as these, a need exists for improved voltage supply and regulation in powering integrated circuits such as processor cores and associated cache memory.

### BRIEF DESCRIPTION OF THE DRAWINGS

The claims provided in this application are not limited by the examples provided in the specification or drawings, but their organization and/or method of operation, together with features, and/or advantages may be best understood by reference to the examples provided in the following detailed description and in the drawings, in which:

FIG. 1 is a side view of an integrated circuit assembly comprising a vertically integrated voltage regulator and a printed circuit board with a hole configured to accommodate the vertically integrated voltage regulator, consistent with an example embodiment.

FIG. 2 is a side view of an integrated circuit assembly comprising vertically integrated voltage regulators mounted to a printed circuit board with a hole configured to accommodate the vertically integrated voltage regulators, consistent with an example embodiment.

FIG. 3 is a side view of an integrated circuit assembly comprising a vertically integrated voltage regulator assembly having separate power connections and a printed circuit board with a hole configured to accommodate the vertically integrated voltage regulator, consistent with an example embodiment.

FIG. 4 is a side view of an integrated circuit assembly comprising an alternate vertically integrated voltage regulator assembly having separate power connections and a printed circuit board with a hole configured to accommodate the vertically integrated voltage regulator, consistent with an example embodiment.

FIG. 5 is a side view of an integrated circuit assembly comprising a vertically integrated voltage regulator and a printed circuit board with a hole configured to accommodate the integrated circuit die, consistent with an example embodiment.

FIG. 6 is a flow diagram of a method of assembling an integrated circuit package with a vertically integrated voltage regulator assembly on a printed circuit board having a hole configured to accommodate the vertically integrated voltage regulator, consistent with an example embodiment.

FIG. 7 shows a block diagram of a general-purpose computerized system, consistent with an example embodiment.

Reference is made in the following detailed description to accompanying drawings, which form a part hereof, wherein like numerals may designate like parts throughout that are corresponding and/or analogous. The figures have not necessarily been drawn to scale, such as for simplicity and/or clarity of illustration. For example, dimensions of some aspects may be exaggerated relative to others. Other embodiments may be utilized, and structural and/or other changes may be made without departing from what is claimed. Directions and/or references, for example, such as up, down, top, bottom, and so on, may be used to facilitate discussion of drawings and are not intended to restrict application of claimed subject matter. The following detailed description therefore does not limit the claimed subject matter and/or equivalents.

### DETAILED DESCRIPTION

In the following detailed description of example embodiments, reference is made to specific example embodiments by way of drawings and illustrations. These examples are described in sufficient detail to enable those skilled in the art to practice what is described, and serve to illustrate how elements of these examples may be applied to various purposes or embodiments. Other embodiments exist, and logical, mechanical, electrical, and other changes may be made.

Features or limitations of various embodiments described herein, however important to the example embodiments in which they are incorporated, do not limit other embodiments, and any reference to the elements, operation, and application of the examples serve only to aid in understanding these example embodiments. Features or elements shown in various examples described herein can be combined in ways other than shown in the examples, and any such combinations is explicitly contemplated to be within the scope of the examples presented here. The following detailed description does not, therefore, limit the scope of what is claimed.

Many modern computing systems employ processors with multiple processing cores, such that certain tasks that can be performed in parallel can be distributed among the cores for faster execution or different tasks can be performed simultaneously by different processors. Simple tasks such as checking an email may only use one processor core, while more complex tasks such as rendering a video game in real time may use all available cores. The processor cores in further examples may be associated with cache memory local to one or more of the respective processor cores, operable to store information that the processor core is likely to need for executing program instructions using local SRAM for fast access.

In some examples the different processor cores may also include different types of circuits, such as high performance processor cores, high efficiency processor cores, memory, and other such circuits. These circuits may vary in power demand, in physical location on the die, and on power demand per unit of area on the die. Powering processor cores and their related caches up and down changes the current drawn from the power source for the processor cores (and, in some further examples, associated cache memory), and may cause a temporary droop in supplied voltage while the voltage regulator or other power supply components recover from the increased demand for power. This voltage droop may be controlled to some degree using methods such as a low-dropout voltage regulator that responds somewhat quickly to changes in drawn current, by using bypass capacitors to store extra charge that is available to help meet a sudden demand for additional current, or through other such means. But, the impedance of low-dropout voltage regulator and the distance between the voltage regulator and the integrated circuit die may limit its ability to respond quickly to changes in power demand. Problems such as these may be exacerbated by high-performance or high-density integrated circuit devices, such as integrated circuits holding hundreds of processor cores for machine learning processing that may consume hundreds or thousands of watts of power.

Some examples presented herein therefore provide for an improved voltage regulator for integrated circuit dies and packages, comprising a printed circuit board with a hole or cutout disposed therein configure to receive a vertically integrated voltage regulator assembly that may overlap or be in the same axis normal to the plane of the integrated circuit die and the voltage regulator assembly circuit board. The voltage regulator assembly may be attached to a substrate to which the integrated circuit die is attached, such as a package substrate, on an opposite mounting surface or opposite side of the substrate as the integrated circuit die, thereby positioning the voltage regulator assembly physically near the integrated circuit die. The hole or cutout formed in a mounting surface of the printed circuit board may in a further example align with a hole in a socket, such that the voltage regulator assembly is physically located at least partially within the cutout in the socket and the cutout in the printed circuit board.

In a more detailed example, an integrated circuit assembly comprises an integrated circuit die, and a substrate electrically and physically coupled to the integrated circuit die on a first mounting surface of the substrate. A printed circuit board has a hole or a cutout formed therein, the substrate operable to be connected to the printed circuit board on the second mounting surface of the substrate. A vertically integrated voltage regulator assembly comprises one or more inductors and one or more voltage regulation circuits, and is electrically and physically connected to the substrate at a physical location on a second mounting surface of the substrate opposite the first mounting surface of the substrate. At least a portion of the vertically integrated voltage regulator assembly and at least a portion of the substrate are intersected by an axis normal to and through the first and second mounting surfaces of the substrate such that the vertically integrated voltage regulator is disposed at least partially within the hole formed in the printed circuit board.

In another example, a method of forming an integrated circuit assembly comprises physically and electrically coupling an integrated circuit die to a first mounting surface of a substrate. A vertically integrated voltage regulator assembly is physically and electrically coupled to the substrate at a physical location on a second mounting surface of the substrate opposite the first mounting surface of the substrate. At least a portion of the vertically integrated voltage regulator assembly and at least a portion of the integrated circuit die are intersected by an axis normal to and through the first and second mounting surfaces, the vertically integrated voltage regulator assembly comprising one or more inductors and one or more voltage regulation circuits. The substrate is electrically and physically coupled to a printed circuit board having a hole or cutout formed therein, the printed circuit board coupled to the substrate either on the second mounting surface of the substrate such that the vertical integrated voltage regulator is physically located at least partially within the hole formed in the printed circuit board, or on the first mounting surface of the substrate such that the integrated circuit die is physically located at least partially within the hold formed in the printed circuit board.

In an alternate example, an integrated circuit assembly comprises an integrated circuit die, and a substrate electrically and physically coupled to the integrated circuit die on a first mounting surface of the substrate. A printed circuit board has a hole or a cutout formed therein, the substrate connected to the printed circuit board on the first mounting surface of the substrate such that the integrated circuit die is physically located at least partially within the hole formed in the printed circuit board. A vertically integrated voltage regulator assembly comprises one or more inductors and one or more voltage regulation circuits, the vertically integrated voltage regulator assembly electrically and physically connected to the substrate at a physical location on a second mounting surface of the substrate opposite the first mounting surface of the substrate. At least a portion of the vertically integrated voltage regulator assembly and at least a portion of the integrated circuit die are intersected by an axis normal to and through the first and second mounting surfaces.

Examples such as these illustrate how a voltage regulator assembly can be mounted physically near an integrated circuit die by positioning the voltage regulator assembly or the integrated circuit die at least partially within a hole or cutout in a printed circuit board, shortening the length and reducing the impedance of electrical connections between the voltage regulator and the integrated circuit die. Such an assembly may allow the voltage regulator to more quickly respond to changes in observed voltage on the integrated circuit die, such as during transients or rapid changes in drawn current, and may provide for more efficient delivery of power to the integrated circuit die with less loss, delay, and other impedance-related or distance-related artifacts.

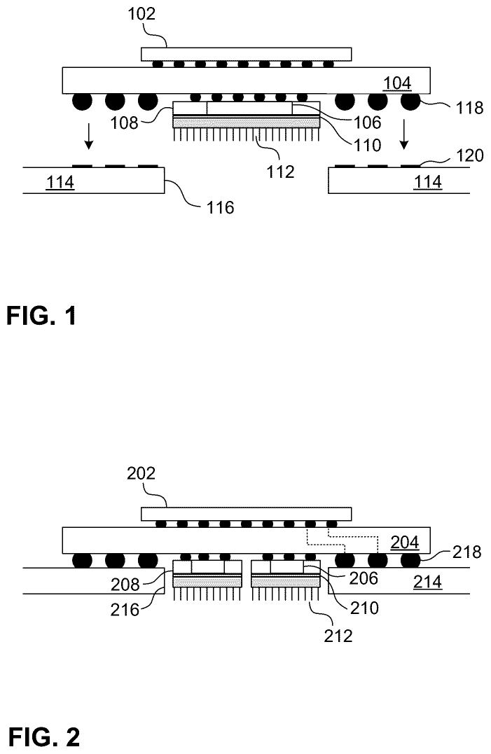

FIG. 1 is a side view of an integrated circuit assembly comprising a vertically integrated voltage regulator and a printed circuit board with a hole configured to accommodate the vertically integrated voltage regulator, consistent with an example embodiment. Here, an integrated circuit die 102 is electrically and physically coupled to a substrate 104. The integrated circuit may in various embodiments comprise various digital analog, or mixed circuits. Digital circuit examples include one or more processor cores, graphics processors, memory, signal processors, and other digital circuits, while analog circuit examples include amplifiers, filters, analog communication circuits, and the like. Mixed signal integrated circuits may contain both digital and analog circuits on the same device, such as a wireless networking integrated circuit operable to process both analog radio waves and digital data signals to facilitate transmission and/or reception of digital data using analog radio waves. The substrate 104 in various examples may comprise a fiberglass and resin, organic laminate, ceramic, or other suitable material, and may contain within one or more conductive layers comprising various signal, power, and other electrical interconnects coupling the flip-chip bumps to ball grid array (BGA) solder balls, Land Grid Array (LGA) contact pads, Pin Grid Array pins, or other package electrical connections.

The substrate 104 in this example is further connected to vertically integrated voltage regulator via an array of flip chip bumps, where the vertically integrated voltage regulator comprises one or more inductors 106, a voltage regulation circuit 108, and a thermal interface 110 coupling the vertically integrated voltage regulator assembly to a heat sink 112. The voltage regulation circuit 108 in various embodiments may be operable to monitor one or more voltage signals on the integrated circuit die 102, and/or monitor one or more voltage signals provided from the vertically integrated voltage regulator assembly to the processor die. The voltage regulator in various examples may be a Low-Dropout Voltage Regulator (LDO voltage regulator) operable to regulate output voltages that are very close to the supply voltage, a linear voltage regulator, or other suitable type of voltage regulator. The voltage regulator may in further examples comprise a DC to DC voltage converter, such as a buck converter or other suitable voltage converter circuit. The voltage regulator circuit in various examples may include one more power components such as one or more inductors (and/or capacitors), which may be physically large relative to other voltage regulator assembly components and so are shown at 106 as being external to the voltage regulation circuit 108.

The vertically integrated voltage regulator assembly in some examples further comprises a thermal interface 110, which is configured to thermally and physically couple to a thermally conductive material such as a heat sink 112 to draw unwanted thermal energy away from the vertically integrated voltage regulator and cool the assembly. The heat sink may in various example embodiments comprise a metal or other thermally conductive material, such as a block of metal having a high thermal mass, a block of metal comprising an array of pins or fins configured to increase surface area to dissipate heat into the surrounding air, or the like. In some further examples, air, liquid, or other material may be circulated in contact with the heat sink to carry heat away from the heat sink, such as via a fan or a pump. The vertically integrated voltage regulator may further be coupled to a heat sink via a thermal interface 110, such as thermal paste, thermal tape, or other material designed to fill any gaps and ensure good thermal conductivity between the vertically integrated voltage regulator and a heat sink.

The integrated circuit assembly shown at 102-112 comprises in the example of FIG. 1 a die, a substrate, and a vertically integrated voltage regulator that may be coupled to a printed circuit board or otherwise coupled to a circuit such as a computerized system via electrical contacts, such as a Ball Grid Array (BGA) of solder balls 118 that couple the integrated circuit assembly to pads 120 on a printed circuit board 114. The solder balls 118 in other examples may comprise metal pillars, such as solder-coated copper pillars, designed to provide greater current-carrying capacity than solder alone, or other types of bumps, pins, and/or the like. The assembly shown at 102-112 may in other embodiments comprise additional components, such as underfill material filling gaps between solder balls in the flip chip ball gird arrays, a protective package covering the top of the die 102 and providing thermal conductivity to a heat sink for the integrated circuit die, and other such components. The printed circuit board 114 in the example of FIG. 1 comprises a hole or a cutout 116 formed in the printed circuit board, such that when the assembly shown at 102-112 is mounted to the printed circuit board via the ball grid array, the vertically integrated voltage regulator assembly shown at 106-112 is disposed at least partially within the hole or cutout formed in the printed circuit board.

The die 102, substrate 104, and vertically integrated voltage regulator comprising inductors 106 and voltage regulator circuit 108 are configured in the example of FIG. 1 such that the vertically integrated voltage regulator is physically near the integrated circuit die, and electrical connections between the two via substrate 104 are relatively short and have a relatively low impedance. This enables relatively rapid response to detected changes in voltage in the integrated circuit die 102, and relatively low losses due to impedance or physical distance between the vertically integrated voltage regulator and the integrated circuit die. The configuration of FIG. 1 may therefore be able to respond to changes in power demand, such as may cause voltage transients, better than other known configurations, and may experience less loss or delay in responding to changes in power demand due to the physical proximity and reduced impedance between the vertically integrated voltage regulator and the integrated circuit die.

The hole or cutout 116 in various examples may be of different sizes, shapes, and other configurations to accommodate the vertically integrated voltage regulator assembly 106-112, such that the vertically integrated voltage regulator assembly may be at least partially disposed within the hole or cutout when the integrated circuit assembly 102-112 is mounted to the printed circuit board 114. The terms “hole” and “cutout” are inclusive of all such sizes, shapes, and configurations, and are not limited to certain configurations or to the examples described here and shown in the drawings.

In an alternate example, the integrated circuit assembly comprising elements 102-112 may mount to the printed circuit board physically and/or electrically via other means, such as a socket (not shown). The socket in such examples may have a hole or cutout corresponding to a the hole or cutout on the printed circuit board, such that when the integrated circuit assembly is mounted in the socket, the vertically integrated voltage regulator assembly is disposed at least partially within the hole or cutout in the socket and the hole or cutout in the printed circuit board. In a more detailed example, a Land Grid Array (LGA) socket having a hole or cutout comprises an array of semi-flexible pins that are operable to make physical and electrical contact with a corresponding array of conductive pads on the substrate 104. The socket may be coupled to the printed circuit board via solder balls such as a ball grid array, and may be underfilled such as with an epoxy resin or other material that flows via capillary action to fill air space between the socket and the printed circuit board 114 to prevent thermal stress from heating and cooling air pockets between the socket and the printed circuit board. The socket 112 in other examples may be another type of socket, such as a pin socket, a Pin Grid Array (PGA) socket, or another suitable socket having a hole or cutout disposed therein to accommodate the vertically integrated voltage regulator assembly 106-112 and designed or configured to physically and electrically connect to the substrate 104. Circuit traces on the printed circuit board 120 may be thereby electrically connected to the integrated circuit die 102 via the socket and the substrate, and the various physical and electrical connection mechanisms that may be employed to couple these components to one another.

FIG. 2 is a side view of an integrated circuit assembly comprising vertically integrated voltage regulator assemblies mounted to a printed circuit board with a hole configured to accommodate the vertically integrated voltage regulators, consistent with an example embodiment. Here, the integrated circuit assembly comprising integrated circuit die 202, substrate 204, and vertically integrated voltage regulator assemblies 206-212 (as shown in the top portion of FIG. 1) may be lowered into position on printed circuit board 214, aligning the ball grid array balls 118 of FIG. 1 with the pads 120 on the printed circuit board and aligning the vertically integrated voltage regulator assemblies to be at least partially disposed within hole or cutout 216 of the printed circuit board. The example shown in FIG. 2 comprises multiple vertically integrated voltage regulator assemblies rather than a single vertically integrated voltage regulator assembly as shown in FIG. 1, enabling different voltage regulator assemblies to provide different regulated voltages to integrated circuit 202, to supply power to different processor cores or other such circuits on integrated circuit 202, and/or to perform other such functions.

When mounted, the Ball Grid Array (BGA) balls 218 on the socket physically contact conductive pads on the printed circuit board 214, providing electrical signal connections between the circuitry on the printed circuit board 214 and the integrated circuit die 202. Dashed lines represent electrical connections, such as metal wire or circuit board traces, linking the substrate 204's ball grid array balls coupling the substrate to the printed circuit board and the land grid array pins coupling the substrate to the integrated circuit die via flip chip ball grid array solder balls, completing an electrical connection between the printed circuit board 220 and the mounted integrated circuit assembly's integrated circuit die 202. Some such connections may provide one or more power supply signals, and may in various examples be routed via flip chip ball grid array solder balls or another suitable electrical connection to the vertically integrated voltage regulator assembly 206-212, enabling the vertically integrated voltage regulator assembly to regulate the voltage of power signals used to power various circuits within the integrated circuit die 202. In some examples, solder balls 218 may comprise metal pillars, such as solder-coated copper pillars, designed to provide greater current-carrying capacity than solder alone, and/or other types of bumps, pins, or the like. Similar connections may also be used to couple the substrate 204 to one or more vertically integrated voltage regulator assemblies 206-212.

In the particular example of FIG. 2, more than one vertically integrated voltage regulator assembly may be present per integrated circuit die, such as to provide different voltage levels for different processor cores on a die and/or to provide power to more than one integrated circuit die. This may be achieved in some examples by using a defined pattern for vertically integrated voltage regulator interface, such as a defined or repeatable interface pattern through one or more layers of the assembly as shown by the pair of vertically integrated voltage regulator assemblies shown at 206-212. This pattern may be repeated multiple times on a single integrated circuit, substrate, or voltage regulator interface, such as a ball grid array, or may be in a standard configuration repeated across different applications such that standardized vertically integrated voltage regulator assemblies may be selected and coupled to integrated circuit die and substrate assemblies.

Some computerized devices may support more than one mounted integrated circuit and/or vertically integrated voltage regulator, such as a printed circuit board serving as a motherboard for a server that may contain many separate integrated circuit dies and associated vertically integrated voltage regulators. In one such example, a printed circuit board motherboard may have tens of integrated circuits dies and associated substrates attached, each having one or more vertically integrated voltage regulators providing power for the various processor cores on each integrated circuit die through a standardized or repeatable interface such as a pattern of flip chip ball grid array balls. Further examples may comprise multiple integrated circuit dies per substrate, either directly coupled to the substrate or mounted to one or more interposers coupling the dies to the substrate

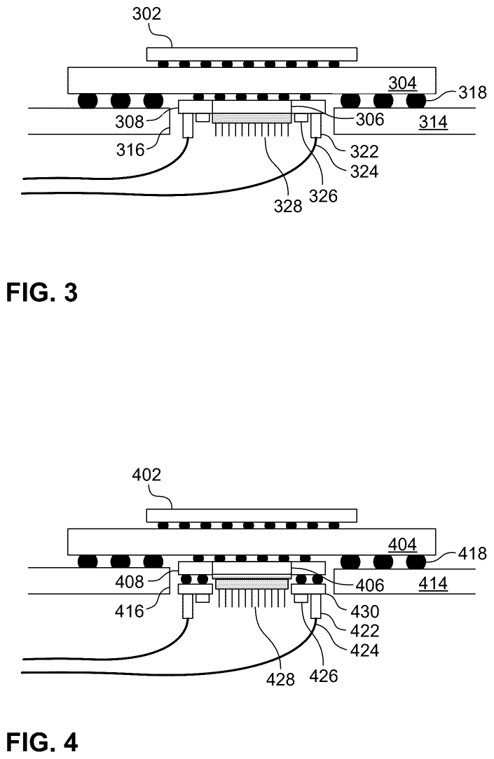

FIG. 3 is a side view of an integrated circuit assembly comprising a vertically integrated voltage regulator assembly having separate power connections and a printed circuit board with a hole configured to accommodate the vertically integrated voltage regulator, consistent with an example embodiment. Here, an integrated circuit die 302 is attached to a substrate 304 such as using a flip chip ball grid array and underfill, similar to the example of FIG. 1. A vertically integrated voltage regulator assembly comprising one or more inductors 306, voltage regulation circuitry 308, and other components is similarly mounted to the substrate 304. A printed circuit board 314 has a cavity 316 formed therein, configured to at least partially receive the vertically integrated voltage regulator assembly.

The vertically integrated voltage regulator assembly in this example further comprises one or more external electrical connections 322 provided by a separate wire 324 rather than via the printed circuit board 314 and substrate 304, such as a high voltage and/or high current wire coupled to a power source. The external electrical connections in various examples may be connected via a terminal or socket as shown at 322, or may be soldered or otherwise attached to the vertically integrated voltage regulator circuitry 308. The vertically integrated voltage regulator assembly in this example further comprises one or more capacitors 326, such as bypass capacitors or similar capacitors configured to store energy for use in voltage regulation, such as to mitigate voltage droop during transients in power drawn by the integrated circuit die 302. The hole or cutout 316 in the printed circuit board 314 enables the vertically integrated voltage regulator assembly to accommodate additional components, such as capacitors 326, and external electrical connections, such as external electrical connections 322 and wires 324 such as may be used to provide external input power and ground signals. In the example shown here, a heat sink 328 is further thermally and physically coupled to at least the inductor 306 portion of the vertically integrated voltage regulator assembly, and is able to dissipate thermal energy in ambient air due at least in part to the cutout or hole 316 in printed circuit board 314.

The integrated circuit assembly comprising the integrated circuit die 302, substrate 304, and vertically integrated voltage regulator assembly are configured in the example of FIG. 3 to be coupled to a printed circuit board 314 via a ball grid array, comprising an array of solder bumps 318 on the substrate 304 and an array of conductive pads on the printed circuit board configured to receive and be electrically and physically coupled to the ball grid array's solder bumps 318. In a more detailed example, the solder bumps 318 of the ball grid array are formed on pads on the substrate 304, and are heated upon mating the integrated circuit assembly to the printed circuit board 314, causing the solder bumps to melt and link pads on substrate 304 with a corresponding array of pads on the printed circuit board 314.

The external electrical connections 322 of FIG. 3 may enable a voltage regulator to receive relatively high current input in a small form factor in some embodiments, such as having a high surface contact area relative to an overall diameter of connectors 322 and/or wires 324. In a more detailed example, such connectors may comprise pin and sleeve connectors, bullet plug or banana plug connectors, and/or the like, which in further examples may comprise a locking feature such as a snap lock, twist-to-lock, and/or the like. Providing power via external power connectors 322 may further enable solder balls and/or bumps connecting the voltage regulator assembly to substrate 304 to be dedicated to providing power to integrated circuit 302. This may also simplify design of the voltage regulator circuit 308, the substrate 304, and the printed circuit board 314, allowing these devices to be more compact, as these components no longer need to carry a high voltage power signal to the voltage regulator circuit 308.

FIG. 4 is a side view of an integrated circuit assembly comprising an alternate vertically integrated voltage regulator assembly having separate power connections and a printed circuit board with a hole configured to accommodate the vertically integrated voltage regulator, consistent with an example embodiment. Here, the integrated circuit assembly and printed circuit board are similar to those shown in the example illustrated in FIG. 3, except that the vertically integrated voltage regulator assembly comprises additional components, such as an additional circuit layer 430 mounted to the vertically integrated voltage array circuitry 408.

This additional circuit layer 430 may in various examples comprise additional voltage control circuitry, such as switching, detecting, and similar components, and/or may serve as a mounting interface for physically large external components or connections such as capacitors 426 and external electrical connections 422. As in the other examples presented herein, solder bumps and/or balls connecting the various elements shown here may comprise in various embodiments metal pillars, such as solder-coated copper pillars, designed to provide greater current-carrying capacity than solder alone, and/or other types of bumps, pins, and/or the like. The hole 416 in printed circuit board 414 is able to accommodate additional components on the vertically integrated voltage regulator assembly, such as multiple circuit layers coupled to one another with flip chip ball grid arrays or other suitable interconnections, due to the additional space adjacent to the substrate 404 opposite the integrated circuit die 402 provided by the hole or cutout 416 in the printed circuit board 414. Such additional space for additional vertically integrated voltage regulator components may be of particular interest in embodiments where the vertically integrated voltage regulator assembly provides more than one supply voltage to the integrated circuit die 402 or provides an atypically high amount of power to the integrated circuit die (such as many hundreds of watts or a kilowatt or more of electrical power).

The examples of FIGS. 1-4 provide for configuration of at least a portion of the vertically integrated voltage regulator assembly and at least a portion of the integrated circuit die to be intersected by an axis normal to and through the mounting surfaces of the integrated circuit die and the vertically integrated voltage regulator assembly. The vertically integrated voltage regulator assembly may further be significantly larger than might fit between the substrate and the printed circuit board due to a hole or cutout in the printed circuit board configured to accommodate at least a portion of the vertically integrated voltage regulator assembly. Such a configuration places the vertical integrated voltage regulator physically close to the integrated circuit die, such that physical distance and electrical impedance between the vertically integrated voltage regulator and the integrated circuit die are low.

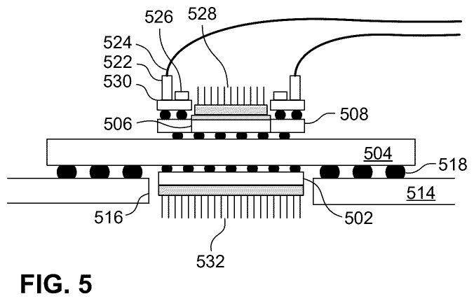

FIG. 5 is a side view of an integrated circuit assembly comprising a vertically integrated voltage regulator and a printed circuit board with a hole configured to accommodate the integrated circuit die, consistent with an example embodiment. Here, an integrated circuit die 502 is mounted to a substrate 504 such as via an underfilled flip chip ball grid array, similar to other examples presented herein. The substrate is mounted to the printed circuit board 514 using a traditional Ball Grid Array (BGA), Land Grid Array (LGA), solder-coated metal pillars, or similar technology, electrically coupling the integrated circuit die 502 to circuit traces comprising a part of the printed circuit board 514.

A vertically integrated voltage assembly comprising inductors 506 and vertically integrated voltage circuits 508 is mounted to a mounting surface of the substrate opposite the mounting surface to which the integrated circuit die 502 and printed circuit board 514 are mounted, positioning the vertically integrated voltage regulator assembly physically near the integrated circuit die to provide low impedance and physical wire length between the vertically integrated voltage regulator assembly and the integrated circuit die. The assembly is substantially similar to the example shown in FIG. 4, except that the mounted components are inverted with respect to the printed circuit board mounting surface such that the hole 516 in the printed circuit board accommodates the integrated circuit 502 and heat sink 532 rather than the vertically integrated voltage regulator assembly. Because the integrated circuit die, packaging, and heat sink are at least partially located within the hole or cutout 516 in the printed circuit board, there is sufficient space on the side of substrate 504 opposite the vertically integrated voltage regulator components to accommodate the integrated circuit die and associated components. Placing the vertically integrated voltage regulator on the top mounting surface of the printed circuit board as shown in FIG. 5 may further provide additional space for vertically integrated voltage regulator components such as additional voltage regulator circuit layers 530, exterior electrical connections 522 and wires 524, and capacitors 526 that may otherwise undesirably extend below the lower surface of the printed circuit board. Connection of external electrical connections 522 and wires 524 may further be easier with the integrated circuit die and vertically integrated voltage regulator assembly configured as shown in FIG. 5 than in the example of FIG. 4 in embodiments where physical access, internal space within the computerized system, or other such constraints make creating such connections at the top side of the printed circuit board desirable.

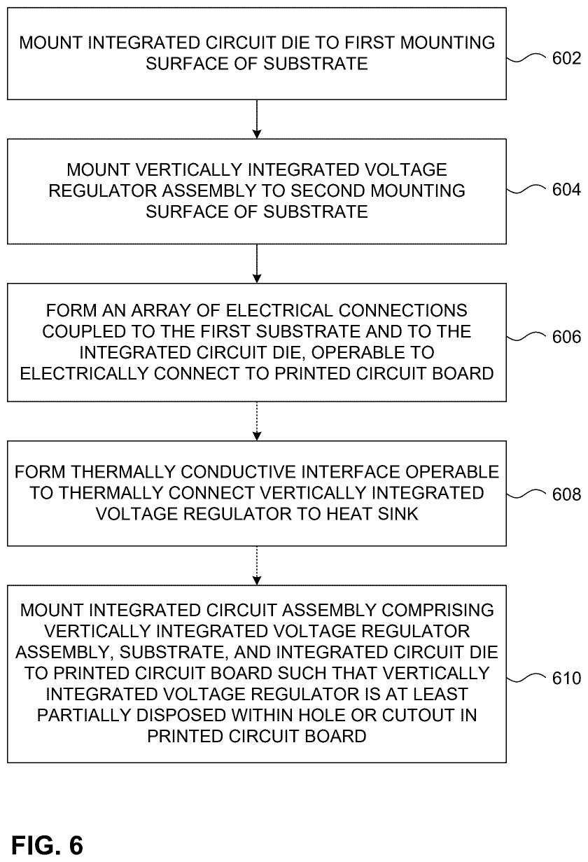

FIG. 6 is a flow diagram of a method of assembling an integrated circuit package with a vertically integrated voltage regulator assembly on a printed circuit board having a hole configured to accommodate the vertically integrated voltage regulator, consistent with an example embodiment. At 602, an integrated circuit die is mounted to a substrate, such as using a flip-chip ball grid array or other suitable method. An underfill may be applied, such as via capillary action, to fill any air space between the integrated circuit die and the substrate. A vertically integrated voltage regulator assembly is mounted to the substrate at 604, such as on a mounting surface opposite the mounting surface to which the integrated circuit die is mounted. Similar methods such as flip chip ball grid array mounting and underfilling or other such methods may be employed. In a more detailed example, the substrate is mounted to the integrated circuit die and the vertically integrated voltage regulator assembly such that at least a portion of the vertically integrated voltage regulator assembly and at least a portion of the integrated circuit die are intersected by an axis normal to and through their respective mounting surfaces.

An array of electrical connections are formed on the substrate at 606, operable to electronically connect the substrate to a printed circuit board (and/or a socket), and to connect circuits on the printed circuit board to the integrated circuit die via conductive elements in the substrate. The substrate may further conduct electrical power signals to the vertically integrated voltage regulator, enabling the voltage regulator to receive relatively high current power signals, and to provide regulated supply voltage power signals to the integrated circuit die and monitor voltages on the integrated circuit die with relatively low latency and impedance.

At 608, a thermally conductive interface is optionally formed on a surface of the vertically integrated voltage regulator, and is operable to conduct thermal heat away from the vertically integrated voltage regulator toward a heat sink, environmental air, liquid cooling, or the like. In further examples, a fan, pump, or other such means may be employed to move gas or liquid across the heat sink, facilitating transfer of heat away from the heat sink.

The integrated circuit assembly with the vertically integrated voltage regulator may be mounted, such as by a manufacturer, end user, or another party to a printed circuit board for use in a computerized system or other electronic device at 610 by mounting the integrated circuit assembly comprising the vertically integrated voltage regulator assembly, the substrate, and the integrated circuit die to a printed circuit board such that the vertically integrated voltage regulator is at least partially within a hope or cutout formed in the printed circuit board. The hole or cutout in a further example may be of a size, shape, or other configuration to receive the vertically integrated voltage regulator assembly at least partially disposed therein.

The examples presented herein illustrate how a vertically integrated voltage regulator may be positioned physically near an integrated circuit die such that signal travel distance and signal impedance between the vertically integrated voltage regulator and the integrated circuit die are low. A hole or cutout may be formed in a printed circuit board in some examples to receive at least a part of the vertically integrated voltage regulator assembly, which in some examples is desirable to create sufficient space below the substrate for the vertically integrated voltage regulator to reside. One or more external electrical components, such as capacitors, and one or more external electrical connections, such as power supply signals, may further be coupled to the vertically integrated voltage regulator, facilitated at least in part by the vertically integrated voltage regulator being accessible through the hole in the printed circuit board when mounted. A heat sink or thermal interface from the vertically integrated voltage regulator may further be provided in some examples, providing a thermal connection between the vertically integrated voltage regulator and the mounting surface (such as a socket, printed circuit board, heat sink portion, or the like), enabling the mounting surface to carry heat away from the vertically integrated voltage regulator and to be dispersed.

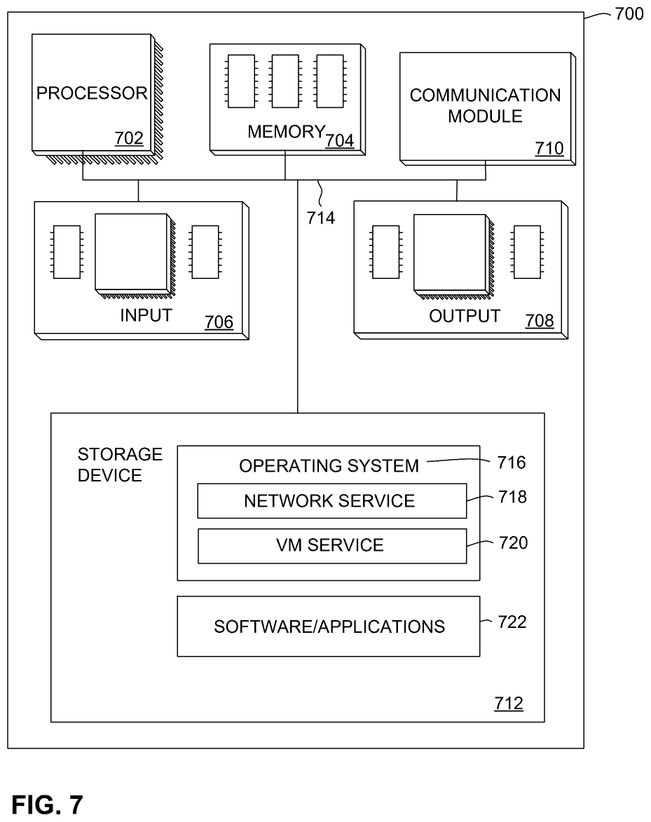

FIG. 7 shows a block diagram of a general-purpose computerized system, consistent with an example embodiment. FIG. 7 illustrates only one particular example of computing device 700, and other computing devices 700 may be used in other embodiments. Although computing device 700 is shown as a standalone computing device, computing device 700 may be any component or system that includes one or more processors or another suitable computing environment for executing software instructions in other examples, and need not include all of the elements shown here.

As shown in the specific example of FIG. 7, computing device 700 includes one or more processors 702, memory 704, one or more input devices 706, one or more output devices 708, one or more communication modules 710, and one or more storage devices 712. Computing device 700, in one example, further includes an operating system 716 executable by computing device 700. The operating system includes in various examples services such as a network service 718 and a virtual machine service 720 such as a virtual server. One or more applications, such as application 722 are also stored on storage device 712, and are executable by computing device 700.

Each of components 702, 704, 706, 708, 710, and 712 may be interconnected (physically, communicatively, and/or operatively) for inter-component communications, such as via one or more communications channels 714. In some examples, communication channels 714 include a system bus, network connection, inter-processor communication network, or any other channel for communicating data. Applications such as software application 722 and operating system 716 may also communicate information with one another as well as with other components in computing device 700.

Processors 702, in one example, are configured to implement functionality and/or process instructions for execution within computing device 700. For example, processors 702 may be capable of processing instructions stored in storage device 712 or memory 704. Examples of processors 702 include any one or more of a microprocessor, a controller, a central processing unit (CPU), a graphics processing unit (GPU), a neural processing unit (NPU), an image signal processor (ISP), a digital signal processor (DSP), an application specific integrated circuit (ASIC), a field-programmable gate array (FPGA), or similar discrete or integrated logic circuitry.

One or more storage devices 712 may be configured to store information within computing device 700 during operation. Storage device 712, in some examples, is known as a computer-readable storage medium. In some examples, storage device 712 comprises temporary memory, meaning that a primary purpose of storage device 712 is not long-term storage. Storage device 712 in some examples is a volatile memory, meaning that storage device 712 does not maintain stored contents when computing device 700 is turned off. In other examples, data is loaded from storage device 712 into memory 704 during operation. Examples of volatile memories include random access memories (RAM), dynamic random access memories (DRAM), static random access memories (SRAM), and other forms of volatile memories known in the art. In some examples, storage device 712 is used to store program instructions for execution by processors 702. Storage device 712 and memory 704, in various examples, are used by software or applications running on computing device 700 such as software application 722 to temporarily store information during program execution.

Storage device 712, in some examples, includes one or more computer-readable storage media that may be configured to store larger amounts of information than volatile memory. Storage device 712 may further be configured for long-term storage of information. In some examples, storage devices 712 include non-volatile storage elements. Examples of such non-volatile storage elements include magnetic hard discs, optical discs, floppy discs, flash memories, or forms of electrically programmable memories (EPROM) or electrically erasable and programmable (EEPROM) memories.

Computing device 700, in some examples, also includes one or more communication modules 710. Computing device 700 in one example uses communication module 710 to communicate with external devices via one or more networks, such as one or more wireless networks. Communication module 710 may be a network interface card, such as an Ethernet card, an optical transceiver, a radio frequency transceiver, or any other type of device that can send and/or receive information. Other examples of such network interfaces include Bluetooth, 4G, LTE, or 5G, WiFi radios, and Near-Field Communications (NFC), and Universal Serial Bus (USB). In some examples, computing device 700 uses communication module 710 to wirelessly communicate with an external device such as via a public network.

Computing device 700 also includes in one example one or more input devices 706. Input device 706, in some examples, is configured to receive input from a user through tactile, audio, or video input. Examples of input device 706 include a touchscreen display, a mouse, a keyboard, a voice responsive system, video camera, microphone or any other type of device for detecting input from a user.

One or more output devices 708 may also be included in computing device 700. Output device 708, in some examples, is configured to provide output to a user using tactile, audio, or video stimuli. Output device 708, in one example, includes a display, a sound card, a video graphics adapter card, or any other type of device for converting a signal into an appropriate form understandable to humans or machines. Additional examples of output device 708 include a speaker, a light-emitting diode (LED) display, a liquid crystal display (LCD or OLED), or any other type of device that can generate output to a user.

Computing device 700 may include operating system 716. Operating system 716, in some examples, controls the operation of components of computing device 700, and provides an interface from various applications such as software application 722 to components of computing device 700. For example, operating system 716, in one example, facilitates the communication of various applications such as software application 722 with processors 702, communication unit 710, storage device 712, input device 706, and output device 708. Applications such as application 722 may include program instructions and/or data that are executable by computing device 700. These and other program instructions or modules may include instructions that cause computing device 700 to perform one or more of the other operations and actions described in the examples presented herein.

Process cores, bitcell arrays, memory structures, peripheral circuitry, and other circuits as described herein in particular examples may be formed in whole or in part by and/or expressed in transistors and/or lower metal interconnects (not shown) in processes (e.g., front end-of-line and/or back-end-of-line processes) such as processes to form complementary metal oxide semiconductor (CMOS) circuitry. The various blocks, neural networks, and other elements disclosed herein may be described using computer aided design tools and expressed (or represented), as data and/or instructions embodied in various computer-readable media, in terms of their behavioral, register transfer, logic component, transistor, layout geometries, and/or other characteristics.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, System Verilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and System Verilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Features of example computing devices employed in example embodiments may comprise features, for example, of a client computing device and/or a server computing device. The term computing device, in general, whether employed as a client and/or as a server, or otherwise, refers at least to a processor and a memory connected by a communication bus. A “processor” and/or “processing circuit” for example, is understood to connote a specific structure such as a central processing unit (CPU), digital signal processor (DSP), graphics processing unit (GPU), image signal processor (ISP) and/or neural processing unit (NPU), or a combination thereof, of a computing device which may include a control unit and an execution unit. In an aspect, a processor and/or processing circuit may comprise a device that fetches, interprets and executes instructions to process input signals to provide output signals. As such, in the context of the present patent application at least, this is understood to refer to sufficient structure within the meaning of 35 USC § 112(f) so that it is specifically intended that 35 USC § 112(f) not be implicated by use of the term “computing device,” “processor,” “processing unit,” “processing circuit” and/or similar terms; however, if it is determined, for some reason not immediately apparent, that the foregoing understanding cannot stand and that 35 USC § 112(f), therefore, necessarily is implicated by the use of the term “computing device” and/or similar terms, then, it is intended, pursuant to that statutory section, that corresponding structure, material and/or acts for performing one or more functions be understood and be interpreted to be described at least in FIG. 1 and in the text associated with the foregoing figure(s) of the present patent application.

Some embodiments may be described, at least in part, by the following numbered clauses or by any combination thereof:

Clause 1: An assembly, comprising: an integrated circuit die; a substrate electrically and physically coupled to the integrated circuit die on a first mounting surface of the substrate; a printed circuit board having a hole formed therein, the substrate to be connected to the printed circuit board on the second mounting surface of the substrate; and a vertically integrated voltage regulator assembly comprising one or more inductors and one or more voltage regulation circuits, the vertically integrated voltage regulator assembly electrically and physically connected to the substrate at a physical location on a second mounting surface of the substrate opposite the first mounting surface of the substrate, wherein at least a portion of the vertically integrated voltage regulator assembly and at least a portion of the substrate are intersected by an axis normal to and through the first and second mounting surfaces of the substrate such that the vertically integrated voltage regulator is disposed at least partially within the hole formed in the printed circuit board.

Clause 2: The assembly of clause 1, further comprising an array of electrical connections coupling the substrate to the printed circuit board.

Clause 3: The assembly of clause 2 or any of the aforementioned clauses, wherein the array of electrical connections comprise a socket mounted to the printed circuit board and a Land Grid Array (LGA) or a Pin Grid Array (PGA), or a combination thereof, the socket further comprising a hole formed therein at least partially aligned with the hole formed in the printed circuit board.

Clause 4: The assembly of any of the aforementioned clauses, further comprising at least one additional integrated circuit die electrically coupled to the substrate and/or an interposer electrically and physically coupling the integrated circuit die and the at least one additional integrated circuit die to the substrate.

Clause 5: The assembly of any of the aforementioned clauses, wherein: the vertically integrated voltage regulator assembly further comprises a first mounting surface physically connected to the second mounting surface of the substrate; and the assembly further comprises a heat sink physically and thermally coupled to the vertically integrated voltage regulator assembly on a second mounting surface of the vertically integrated voltage regulator assembly opposite the first mounting surface of the voltage regulator assembly.

Clause 6: The assembly any of the aforementioned clauses, further comprising at least one electrical connection operable to couple the vertically integrated voltage regulator assembly to a power supply signal.

Clause 7: The assembly of clause 6 or any of the aforementioned clauses, wherein the at least one electrical connection to be operable to couple the vertical integrated voltage regulator assembly to a power supply signal comprises at least one wire coupled to a power connector on the vertically integrated voltage regulator

Clause 8: The assembly of clause 6 or any of the aforementioned clauses, wherein the at least one electrical connection is operable to carry an electrical signal having power of a kilowatt or greater.

Clause 9: The assembly of clause 6 or any of the aforementioned clauses, wherein the vertically integrated voltage regulator assembly is operable to reduce a voltage of the power supply signal by at least a factor of ten.

Clause 10: A method of forming an integrated circuit assembly, comprising: physically and electrically coupling an integrated circuit die to a first mounting surface of a substrate; physically and electrically coupling a vertically integrated voltage regulator assembly to the substrate at a physical location on a second mounting surface of the substrate opposite the first mounting surface of the substrate, wherein at least a portion of the vertically integrated voltage regulator assembly and at least a portion of the integrated circuit die are intersected by an axis normal to and through the first and second mounting surfaces, the vertically integrated voltage regulator assembly comprising one or more inductors and one or more voltage regulation circuits; and physically and electrically coupling the substrate to a printed circuit board having a hole formed therein, the printed circuit board coupled to the substrate either on the second mounting surface of the substrate such that the vertical integrated voltage regulator is physically located at least partially within the hole formed in the printed circuit board, or on the first mounting surface of the substrate such that the integrated circuit die is physically located at least partially within the hold formed in the printed circuit board.

Clause 11: The method of forming an integrated circuit assembly of clause 10, further comprising coupling the substrate to the printed circuit board via a socket comprising an array of electrical connections, the electrical connections comprising at least one of a Land Grid Array (LGA) or a Pin Grid Array (PGA), the socket further comprising a hole formed therein at least partially aligned with the hole formed in the printed circuit board.

Clause 12: The method of forming an integrated circuit assembly of any of clauses 10-11, further comprising coupling the substrate to the printed circuit board via an array of electrical connections comprising a Ball Grid Array (BGA).

Clause 13: The method of forming an integrated circuit assembly of any of clauses 10-12, further comprising physically and thermally coupling a heat sink to the vertically integrated voltage regulator assembly on a second mounting surface of the vertically integrated voltage regulator assembly opposite a first mounting surface of the voltage regulator assembly to which the substrate is mounted.

Clause 14: The method of forming an integrated circuit assembly of any of clauses 10-13, further comprising coupling at least one electrical connection comprising a wire to a power connector in the vertically integrated voltage regulator, the at least one electrical connection operable to couple the vertically integrated voltage regulator assembly to a power supply signal.

Clause 15: The method of forming an integrated circuit assembly of clause 14 or any of clauses 10-13, wherein the vertically integrated voltage regulator assembly is operable to reduce a voltage of the power supply signal by at least a factor of ten.

Clause 16: The method of forming an integrated circuit assembly of any of clauses 10-15, further comprising thermally and physically coupling a heat sink to the integrated circuit die on a second mounting surface of the integrated circuit die opposite a first mounting surface of the integrated circuit die to which the substrate is mounted.

Clause 17: An assembly, comprising: an integrated circuit die; a substrate electrically and physically coupled to the integrated circuit die on a first mounting surface of the substrate; a printed circuit board having a hole formed therein, the substrate connected to the printed circuit board on the first mounting surface of the substrate, such that the integrated circuit die is physically located at least partially within the hole formed in the printed circuit board; and a vertically integrated voltage regulator assembly comprising one or more inductors and one or more voltage regulation circuits, the vertically integrated voltage regulator assembly electrically and physically connected to the substrate at a physical location on a second mounting surface of the substrate opposite the first mounting surface of the substrate, wherein at least a portion of the vertically integrated voltage regulator assembly and at least a portion of the integrated circuit die are intersected by an axis normal to and through the first and second mounting surfaces.

Clause 18: The assembly of clause 17, further comprising an array of electrical connections coupling the substrate to the printed circuit board.

Clause 19: The assembly of any of clauses 17-18, further comprising a heat sink physically and thermally coupled to the integrated circuit die, the heat sink physically located at least partially within the hole formed in the printed circuit board.

Clause 20: The assembly of any of clauses 17-19, further comprising at least one electrical connection operable to couple the vertically integrated voltage regulator assembly to a power supply signal.

Although specific embodiments have been illustrated and described herein, any arrangement that achieve the same purpose, structure, or function may be substituted for the specific embodiments shown. This application is intended to cover any adaptations or variations of the example embodiments of the invention described herein. These and other embodiments are within the scope of the following claims and their equivalents.

What is claimed is:

1. An assembly, comprising:
an integrated circuit die;
a substrate electrically and physically coupled to the integrated circuit die on a first mounting surface of the substrate;
a printed circuit board having a hole formed therein, the substrate to be coupled to the printed circuit board on a second mounting surface of the substrate; and
a vertically integrated voltage regulator assembly comprising one or more inductors and one or more voltage regulation circuits, the vertically integrated voltage regulator assembly electrically and physically coupled to the substrate at a physical location on a second mounting surface of the substrate opposite the first mounting surface of the substrate, wherein at least a portion of the vertically integrated voltage regulator assembly and at least a portion of the substrate are intersected by an axis normal to and through the first and second mounting surfaces of the substrate such that the vertically integrated voltage regulator assembly is disposed at least partially within the hole formed in the printed circuit board.

2. The assembly of claim 1, further comprising a set of electrical connections coupling the substrate to the printed circuit board.

3. The assembly of claim 2, wherein the set of electrical connections comprise a socket mounted to the printed circuit board and a Land Grid Array (LGA), a Pin Grid Array (PGA), or a Ball grid Array (BGA), or a combination thereof coupled to the substrate, the socket further comprising a hole formed therein at least partially aligned with the hole formed in the printed circuit board.

4. The assembly of claim 1, further comprising at least one additional integrated circuit die electrically coupled to the substrate and/or an interposer electrically and physically coupling the integrated circuit die and the at least one additional integrated circuit die to the substrate.

5. The assembly of claim 1, wherein:
the vertically integrated voltage regulator assembly further comprises a first mounting surface physically coupled to the second mounting surface of the substrate; and
the assembly further comprises a heat sink physically and thermally coupled to the vertically integrated voltage regulator assembly on a second mounting surface of the vertically integrated voltage regulator assembly opposite the first mounting surface of the voltage regulator assembly.

6. The assembly of claim 1, further comprising at least one electrical connection operable to couple the vertically integrated voltage regulator assembly to a power supply signal.

7. The assembly of claim 6, wherein the at least one electrical connection to be operable to couple the vertical integrated voltage regulator assembly to a power supply signal comprises at least one wire coupled to a power connector on the vertically integrated voltage regulator assembly.

8. The assembly of claim 6, wherein the at least one electrical connection is operable to carry an electrical signal having power of a kilowatt or greater.

9. The assembly of claim 6, wherein the vertically integrated voltage regulator assembly is operable to reduce a voltage of the power supply signal by at least a factor of ten.

10. A method of forming an integrated circuit assembly, comprising:
physically and electrically coupling an integrated circuit die to a first mounting surface of a substrate;
physically and electrically coupling a vertically integrated voltage regulator assembly to the substrate at a physical location on a second mounting surface of the substrate opposite the first mounting surface of the substrate, wherein at least a portion of the vertically integrated voltage regulator assembly and at least a portion of the integrated circuit die are intersected by an axis normal to and through the first and second mounting surfaces, the vertically integrated voltage regulator assembly comprising one or more inductors and one or more voltage regulation circuits; and
physically and electrically coupling the substrate to a printed circuit board having a hole formed therein, the printed circuit board coupled to the substrate either on the second mounting surface of the substrate such that the vertically integrated voltage regulator assembly is physically located at least partially within the hole formed in the printed circuit board, or on the first mounting surface of the substrate such that the integrated circuit die is physically located at least partially within the hole formed in the printed circuit board.

11. The method of forming an integrated circuit assembly of claim 10, further comprising coupling the substrate to the printed circuit board via a socket comprising an array of electrical connections, the electrical connections comprising at least one of a Land Grid Array (LGA) or a Pin Grid Array (PGA), the socket further comprising a hole formed therein at least partially aligned with the hole formed in the printed circuit board.

12. The method of forming an integrated circuit assembly of claim 10, further comprising coupling the substrate to the printed circuit board via an array of electrical connections comprising a Ball Grid Array (BGA).

13. The method of forming an integrated circuit assembly of claim 10, further comprising physically and thermally coupling a heat sink to the vertically integrated voltage regulator assembly on a second mounting surface of the vertically integrated voltage regulator assembly opposite a first mounting surface of the voltage regulator assembly to which the substrate is mounted.

14. The method of forming an integrated circuit assembly of claim 10, further comprising coupling at least one electrical connection comprising a wire to a power connector in the vertically integrated voltage regulator assembly, the at least one electrical connection operable to couple the vertically integrated voltage regulator assembly to a power supply signal.

15. The method of forming an integrated circuit assembly of claim 14, wherein the vertically integrated voltage regulator assembly is operable to reduce a voltage of the power supply signal by at least a factor of ten.

16. The method of forming an integrated circuit assembly of claim 10, further comprising thermally and physically coupling a heat sink to the integrated circuit die on a second mounting surface of the integrated circuit die opposite a first mounting surface of the integrated circuit die to which the substrate is mounted.

17. An assembly, comprising:
an integrated circuit die;
a substrate electrically and physically coupled to the integrated circuit die on a first mounting surface of the substrate;
a printed circuit board having a hole formed therein, the substrate coupled to the printed circuit board on the first mounting surface of the substrate, such that the integrated circuit die is physically located at least partially within the hole formed in the printed circuit board; and
a vertically integrated voltage regulator assembly comprising one or more inductors and one or more voltage regulation circuits, the vertically integrated voltage regulator assembly electrically and physically coupled to the substrate at a physical location on a second mounting surface of the substrate opposite the first mounting surface of the substrate, wherein at least a portion of the vertically integrated voltage regulator assembly and at least a portion of the integrated circuit die are intersected by an axis normal to and through the first and second mounting surfaces.

18. The assembly of claim 17, further comprising a set of electrical connections coupling the substrate to the printed circuit board.

19. The assembly of claim 17, further comprising a heat sink physically and thermally coupled to the integrated circuit die, the heat sink physically located at least partially within the hole formed in the printed circuit board.

20. The assembly of claim 17, further comprising at least one electrical connection operable to couple the vertically integrated voltage regulator assembly to a power supply signal.
